(19) United States
(12) Patent Application Publication
(10) Pub. No.: US 2013/0169521 A1
(43) Pub. Date: Jul. 4, 2013

(54) DISPLAY DEVICE FOR PATTERN RECOGNITION INPUT

(71) Applicants: Sang-Hun LEE, Suwon-si (KR); Yun Ho LEE, Cheonan-si (KR); Yui-Ku LEE, Seoul (KR); Sun-Young CHANG, Gwangmyeong-si (KR); Chul HUH, Yongin-si (KR)

(72) Inventors: Sang-Hun LEE, Suwon-si (KR); Yun Ho LEE, Cheonan-si (KR); Yui-Ku LEE, Seoul (KR); Sun-Young CHANG, Gwangmyeong-si (KR); Chul HUH, Yongin-si (KR)

(73) Assignee: SAMSUNG DISPLAY CO., LTD., Yongin-City (KR)

(21) Appl. No.: 13/472,140

(22) Filed: May 15, 2012

(30) Foreign Application Priority Data
Dec. 30, 2011 (KR) 10-2011-0147732

(51) Int. Cl. G06F 3/01; G09G 3/36; H01L 27/15

(52) U.S. Cl. 345/156; 257/88; 257/E27.121; 345/104

(57) ABSTRACT

A display device includes: a substrate, a plurality of signal lines disposed on the substrate, at least one insulating layer disposed on the substrate, and a plurality of location references disposed on the substrate and in the same layer level as at least one of the signal lines, wherein arrangement of the plurality of location references varies depending on relative locations of the location references on a screen of the display device.

### CROSS-REFERENCE TO RELATED APPLICATION

This application claims priority from and the benefit of Korean Patent Application No. 10-2011-0147732, filed on Dec. 30, 2011, which is hereby incorporated by reference for all purposes as if fully set forth herein.

### BACKGROUND OF THE INVENTION

1. Field of the Invention

Exemplary embodiments of the present invention relate to a display device for pattern recognition input.

2. Discussion of the Background

Recently, more and more mobile devices use a touch screen input that allows input by directly contacting a screen with a finger or a touch pen.

There are several technologies for inputting information into a touch screen, for example, resistive touchscreen, capacitive touchscreen, etc. The capacitive touchscreen is usually used in mobile information devices such as a smart phone.

Unlike the above-described technologies, a technology that provides predetermined patterns on a display device and uses an electronic pen for recognizing the patterns in the display to perform input is suggested. In particular, a set of predetermined patterns that designate certain locations on the display device are formed in advance, and the electronic pen is moved to a desired position and recognizes a pattern on the desired position with a camera mounted on the pointing device such as an electronic pen. Using the recognized pattern, the position of the electronic pen is detected and the input is performed based thereon.

In this technology, a separate film with patterns is attached to the display device, or a layer for a black matrix that covers boundaries of pixels of the display device is patterned to form the patterns. However, the above-described method may cause deterioration of the performance of the display, including the increased thickness of the display device and the decreased luminance of the display panel. Furthermore, the process of manufacturing the display panel may be complicated.

### SUMMARY OF THE INVENTION

Exemplary embodiments of the present invention provide a display device for pattern recognition input.

Additional features of the invention will be set forth in the description which follows, and in part will be apparent from the description, or may be learned by practice of the invention.

An exemplary embodiment of the present invention discloses a display device that includes: a substrate, a plurality of signal lines disposed on the substrate, at least one insulating layer disposed on the substrate, and a plurality of location references disposed on the substrate and in the same layer level as at least one of the signal lines, wherein arrangement of the plurality of location references varies depending on relative locations of the location references on a screen of the display device.

Another exemplary embodiment of the present invention discloses a display device that includes: a first substrate, a gate electrode disposed on the first substrate, a gate insulating layer disposed on the gate electrode, a semiconductor layer disposed on the gate insulating layer, source and drain electrodes disposed on the semiconductor layer, a passivation layer disposed on the source and drain electrodes, and a plurality of location references in the same layer level as the gate electrode or the source and drain electrodes, wherein arrangement of the plurality of location references varies depending on relative locations of the location references on a screen of the display device.

Another exemplary embodiment of the present invention discloses a display device that includes: a substrate, a plurality of signal lines disposed on the substrate, at least one insulating layer disposed on the substrate, a plurality of pixels disposed on the substrate, and a plurality of pattern elements disposed on the substrate in correspondence with some or all of the plurality of pixels, wherein the plurality of pattern elements are grouped into a plurality of location indicators, each of the location indicators has distinct arrangement pattern from the other location indicators, and the plurality of pattern elements are in the same layer level as at least one of the signal lines.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the principles of the invention.

FIG. 1 is a schematic plan view of a display device for pattern recognition input according to an exemplary embodiment.

FIG. 2 is a schematic equivalent circuit diagram of a display device for pattern recognition input according to an exemplary embodiment.

FIG. 3 is a schematic sectional view of a display device for pattern recognition input according to an exemplary embodiment.

FIG. 4 is a schematic sectional view showing an intermediate step of manufacturing a display device shown in FIG. 3.

FIG. 5 is a schematic sectional view of a display device for pattern recognition input according to an exemplary embodiment.

FIG. 6 is a schematic sectional view of a display device for pattern recognition input according to another exemplary embodiment.

FIG. 7 is a schematic sectional view of a liquid crystal display for pattern recognition input according to another exemplary embodiment.

FIG. 8 is a schematic diagram of an electronic input pen that can be used for a display device for pattern recognition input according to an exemplary embodiment.

FIG. 9 is a schematic sectional view showing proceeding and reflecting paths of light incident from a pen on the display device shown in FIG. 3.

### DETAILED DESCRIPTION OF THE ILLUSTRATED EMBODIMENTS

The present invention will be described more fully hereinafter with reference to the accompanying drawings, in which exemplary embodiments of the invention are shown. This invention may, however, be embodied in many different forms and should not be construed as limited to the exemplary embodiments set forth herein. Rather, these exemplary embodiments are provided so that this disclosure is thorough, and will fully convey the scope of the invention to those skilled in the art.

In the drawings, the thickness of layers, films, panels, regions, etc., may be exaggerated for clarity. It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present. In contrast, It will be understood that when an element such as a layer, film, region, or substrate is referred to as being “beneath” another element, it can be directly beneath the other element or intervening elements may also be present. Meanwhile, when an element is referred to as being “directly beneath” another element, there are no intervening elements present. It will be understood that for the purposes of this disclosure, “at least one of X, Y, and Z” can be construed as X only, Y only, Z only, or any combination of two or more items X, Y, and Z (e.g., XYZ, XYY, YZ, ZZ).

Hereinafter, exemplary embodiments of the present invention will be explained in detail with reference to the accompanying drawings.

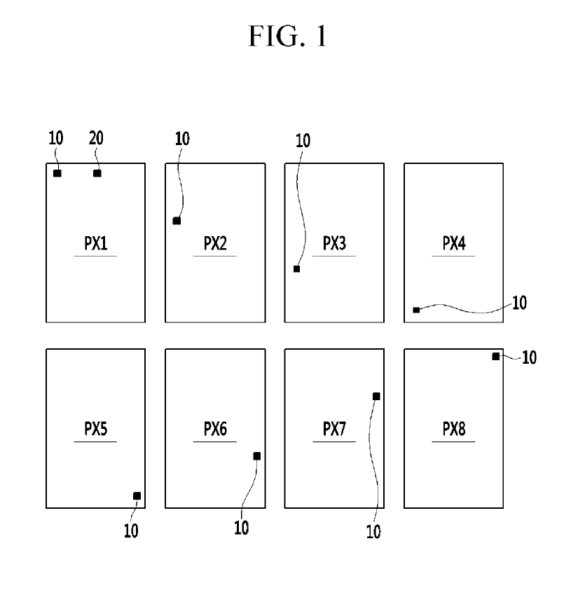

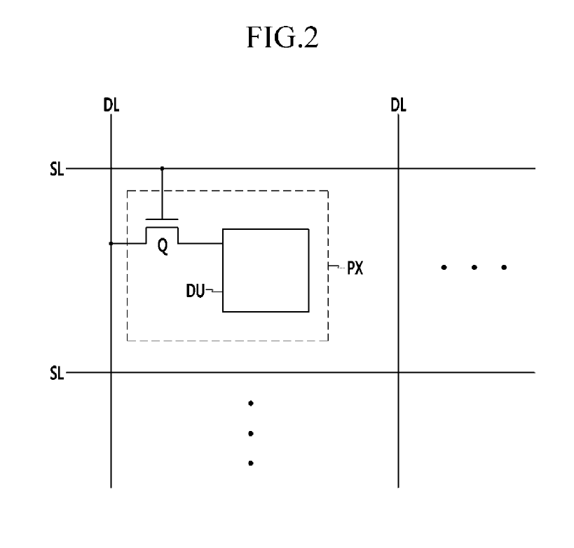

Hereinafter, a display device for pattern recognition input according to an exemplary embodiment will be described in detail with reference to FIG. 1 and FIG. 2.

FIG. 1 is a schematic plan view of a display device for pattern recognition input according to an exemplary embodiment, and FIG. 2 is a schematic equivalent circuit diagram of a display device for pattern recognition input according to the exemplary embodiment.

Referring to FIG. 1, the display device for pattern recognition input according to the present exemplary embodiment may include a plurality of pixels PX1-PX8 to display images that form a screen.

The display device further includes a plurality of pattern elements 10 for the respective pixels PX1-PX8. The pattern elements 10 are provided to designate a relative location of a pointing device on the screen of the display device, and may be disposed at predetermined positions of the respective pixels PX1-PX8. Although the pattern element 10 illustrated in FIG. 1 is a square, it may be triangular, circular, or any other shapes. A pattern element 10 does not need to be provided for every pixel PX1-PX8, and one pattern element 10 may be provided for several among the plurality of the pixels PX1-PX8, or multiple patterns 10 may be provided for a pixel PX1-PX8.

A group of the pattern elements 10 for a group of pixels PX1-PX8 may constitute a unit that forms a pattern or an arrangement that indicates the location on the screen where the group of the pattern elements 10 are located. For example, as illustrated in FIG. 1, the pattern elements 10 for eight pixels PX1-PX8 arranged in a 4×2 matrix may form one location indicator. Different location indicators may represent different locations on the screen, and the arrangement of the pattern elements 10 in one location indicator may be different from the arrangement of the pattern elements 10 in the other location indicators.

In the example shown in FIG. 1, the number of positions in each pixel PX1-PX8 where a pattern element 10 can be disposed is eight, and the number of the pixels PX1-PX8 contributing to a location indicator is eight. Therefore, the location indicator may have one of about 16 million (≈8⁸) different arrangements, and thus may represent one of the same number of locations on the screen.

However, the above-described exemplary embodiment is merely an example, and the shape, available positions, and the density of the pattern elements 10, the number of pixels contributing to a location indicator, and the number and the arrangements of location indicators, etc., may be modified in various manners.

The display device according to the present exemplary embodiment may further include markers 20 to distinguish location indicators. One or more of the markers 20 may be assigned to each of the location indicators, and may be disposed at locations different from the positions of the pattern elements 10. For example, the pattern element 10 may be disposed near the left and right boundaries of the respective pixel, and the marker 20 may be disposed near an upper boundary of the respective pixel. However, the positions of the marker 20 and the pattern element 10 are not limited thereto, and they may be disposed anywhere so long as they are distinguishable from each other.

The locations of the markers 20 for all the location indicators may be the same. For example, the marker 20 for each of the location indicators may be disposed in an uppermost and leftmost pixel PX1 among the pixels PX1-PX8 contributing to a corresponding location indicator as shown in FIG. 1. In this case, if it is assumed that a marker 20 is found in a first pixel. Then, a group of pixels forming a 4×2 matrix and including the first pixel at the upper left corner of the matrix may serve as a unit contributing to a location indicator. If the location of the marker 20 is predetermined otherwise, another group of pixels including the first pixel may serve as a unit contributing to a location indicator.

Although the marker 20 is disposed in an upper left pixel PX1 among the pixels PX1-PX8 contributing to a location indicator in FIG. 1, it may be disposed in a lower right pixel PX8 or another pixel PX2-PX7.

The marker 20 may be omitted, and one or more of the pattern elements 10 may serve as the marker 20.

Referring to FIG. 2, the display device according to the present exemplary embodiment may further include, in addition to the pixels PX, a plurality of signal lines to transmit signals to the pixels PX. FIG. 1 shows two types of signal lines, a plurality of scanning lines SL to transmit scanning signals and a plurality of data lines to transmit image signals. However, according to another exemplary embodiment, the pixels PX may receive only one type of signals, for example, the image signals, and in such exemplary embodiment, the display device may include only one type of the signal lines, for example, the data lines DL. According to another exemplary embodiment, the pixels PX may require three or more types of signals, and in such exemplary embodiment, three kinds of signal lines may be provided on the display device.

Each pixel PX may include a display unit DU that displays images and a switching element Q. The switching element Q may be omitted.

The switching element Q is connected to a signal line SL and a data line DL, and may turn on and off in response to a scanning signal from the scanning line SL, thereby transmitting image signal from the data line DL to the display unit DU. The switching element Q shown in FIG. 1 is a transistor, but other elements having a switching function such as a diode may be used instead of the transistor.

The display unit DU converts an electric image signal into an optical image signal to be displayed.

The display device may include at least one of thin films such as a conductive layer (not shown), an insulating layer (not shown), and a semiconductor layer (not shown). The conductive layer may include the signal lines, the pattern element 10, the marker 20, etc., and the insulating layer may be disposed on or under the conductive layer or the semiconductor layer.

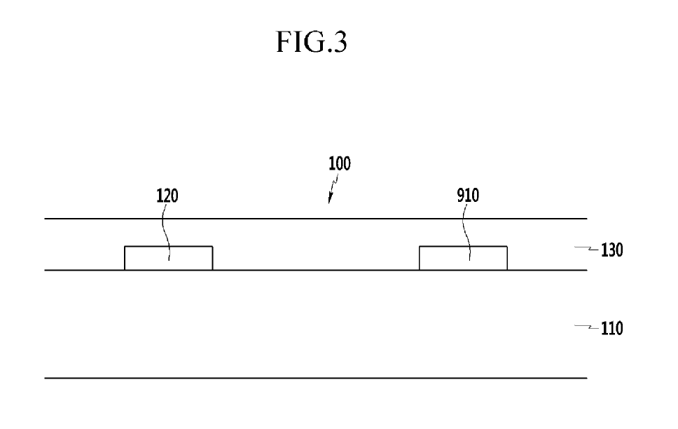

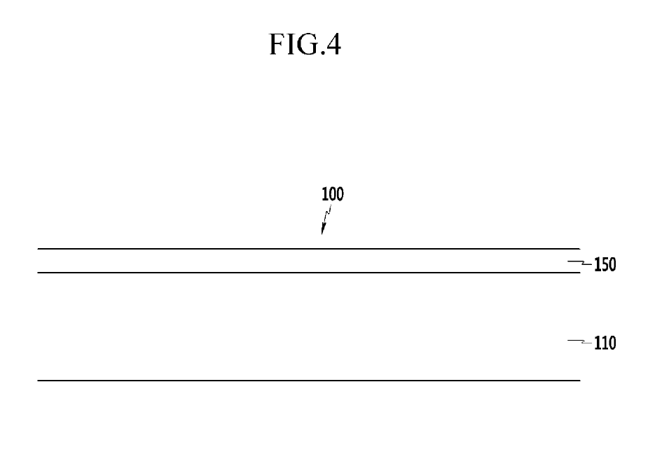

Now, a schematic structure of a display device for pattern recognition input according to an exemplary embodiment will be described in detail with reference to FIG. 3 and FIG. 4.

FIG. 3 is a schematic sectional view of a display device for pattern recognition input according to an exemplary embodiment, and FIG. 4 is a schematic sectional view showing an intermediate step of manufacturing a display device shown in FIG. 3.

Referring to FIG. 3, a display device 100 for pattern recognition input according to an exemplary embodiment includes a substrate 110, conductive members 120 and 910, and the insulating layer 130.

The conductive members 120 and 910 are disposed on the substrate 110, and include a signal line 120 and a pattern element 910.

The insulating layer 130 is disposed on the conductive members 120 and 910. The insulating layer 130 may be disposed on exposed portions of the substrate 110, which are not covered by the conductive members 120 and 910.

One or more other thin films such as a conductive layer (not shown), an insulating layer (not shown), and a semiconductor layer (not shown) may be disposed between the substrate 110 and the conductive members 120 and 910.

In the present exemplary embodiment, the signal line 120 and the pattern element 910 may be formed of a single conductive layer. For example, as shown in FIG. 4, a conductive layer 150 is deposited on the substrate 110 by sputtering, etc., and patterned by photolithography, etc., to form the signal line 120 and the pattern element 910.

A plurality of portions or members formed by patterning a thin film as described above are referred to be “in the same layer level,” and portions or members formed from different thin films are referred to be “in the different layer level.” For example, the signal line 120 and the pattern element 910 shown in FIG. 3 are in the same layer level.

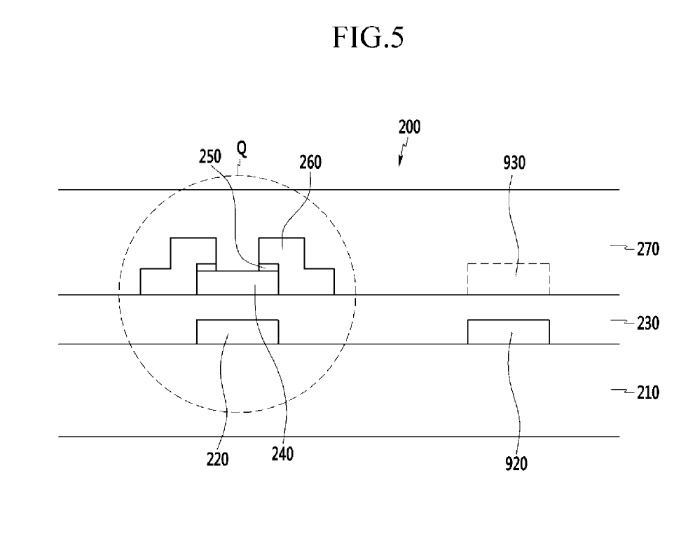

A detailed structure of a display device for pattern recognition input according to an exemplary embodiment will be described in detail with reference to FIG. 5.

FIG. 5 is a schematic sectional view of a display device for pattern recognition input according to an exemplary embodiment.

Referring to FIG. 5, in a display device 200 for pattern recognition input according to an exemplary embodiment, a gate electrode 220 and a pattern element 920 are disposed on a substrate 210, and a gate insulating layer 230 is disposed thereon. A semiconductor layer 240 is disposed on the gate insulating layer 230, and a pair of contact assistants 250 are disposed thereon. Source and drain electrodes 260 are disposed on the contact assistants 250, and a passivation layer 270 is disposed thereon.

The gate electrode 220, the semiconductor layer 240, the contact assistants 250, the source and drain electrodes 260, etc., may constitute a switching element Q.

The pattern element 920 is in the same layer level as the gate electrode 220. However, according to another exemplary embodiment, the pattern element 930 may be in the same layer level as the source and drain electrodes 260 as denoted by dotted lines shown in FIG. 5. One way of disposing the pattern element 920 is to dispose it in the same layer level as the topmost signal line to increase the light reflectance. The marker 20 shown in FIG. 1 may be in the same layer level as the pattern element 920 or 930.

The contact assistants 250 may be omitted.

Referring to FIG. 2 and FIG. 5, the scanning line SL may be connected to the gate electrode 220 and may be in the same layer level as the gate electrode 220. The data line DL may be connected to the source electrode of the source and drain electrodes 260 and may be in the same layer level as the source and drain electrodes 260.

The pattern element 920 and the marker 20 may be separated from the scanning line SL and the gate electrode 220, but it may be connected to the scanning line SL or the gate electrode 220.

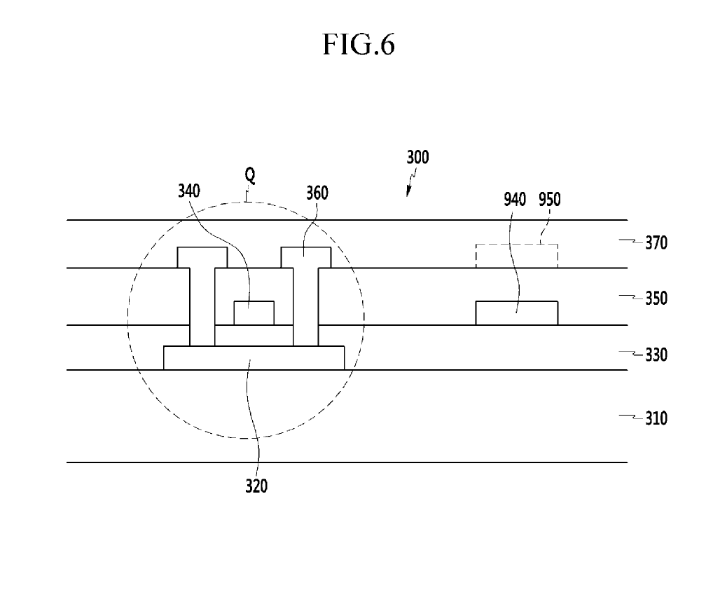

Hereinafter, a detailed structure of a display device for pattern recognition input according to another exemplary embodiment will be described in detail with reference to FIG. 6.

FIG. 6 is a schematic sectional view of a display device for pattern recognition input according to another exemplary embodiment.

Referring to FIG. 6, in a display device 300 for pattern recognition input according to an exemplary embodiment, a semiconductor layer 320 is disposed on a substrate 310, and a gate insulating layer 330 is disposed thereon. A gate electrode 340 and a pattern element 940 are disposed on the gate insulating layer 330, and an interlayer insulating layer 350 is disposed thereon. Source and drain electrodes 360 are disposed on the interlayer insulating layer 350, and a passivation layer 370 is disposed thereon. The source and drain electrodes 360 may be connected to the semiconductor layer 320 through contact holes formed in the gate insulating layer 330 and the interlayer insulating layer 350.

The semiconductor layer 320, the gate electrode 340, the source and drain electrodes 360, etc., constitute a switching element Q.

The pattern element 940 is in the same layer level as the gate electrode 340. However, according to another exemplary embodiment, the pattern element 950 may be in the same layer level as the source and drain electrodes 360 as denoted by dotted lines shown in FIG. 6. The marker 20 shown in FIG. 1 may be in the same layer level as the pattern element 940 or 950.

As shown in FIG. 2 and FIG. 6, the scanning line SL may be connected to the gate electrode 340 and may be in the same layer level as the gate electrode 340. The data line DL may be connected to the source electrode of the source and drain electrodes 360 and may be in the same layer level as the source and drain electrodes 360.

The pattern element 940 or 950 and the marker 20 may be separated from the scanning line SL and the gate electrode 340, but it may be connected to the scanning line SL or the gate electrode 340.

The above-described structures may be applied to a flat panel display such as a liquid crystal display. While the present exemplary embodiment, and other embodiments thereafter, is disclosed with regard to a liquid crystal display, the exemplary embodiments disclosed herein may be used in various displays such as flat panel displays, organic light luminescence devices and so on.

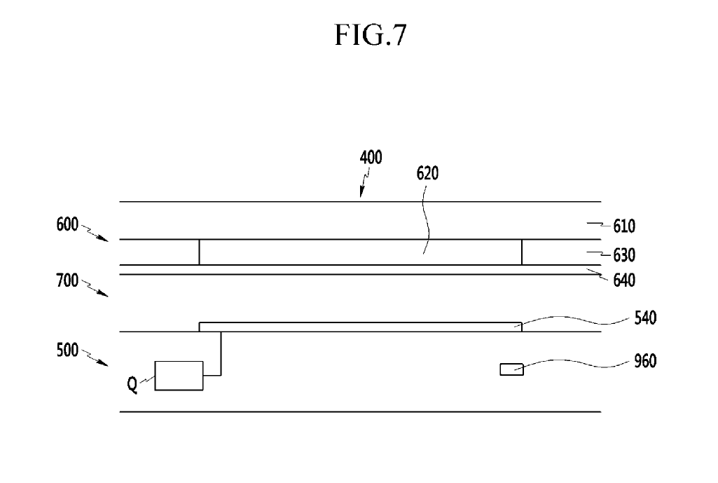

Hereinafter, a liquid crystal display for pattern recognition input according to an exemplary embodiment will be described in detail with reference to FIG. 7.

FIG. 7 is a schematic sectional view of a liquid crystal display for pattern recognition input according to an exemplary embodiment.

Referring to FIG. 7, a liquid crystal display 400 for pattern recognition input according to an exemplary embodiment includes a lower display panel 500 and an upper display panel 600 facing each other, and a liquid crystal layer 700 disposed therebetween.

The lower display panel 500 may include a plurality of signal lines such as scanning lines (SL shown in FIG. 2) and data lines (DL shown in FIG. 2), a switching element Q, a pattern element 960 and a pixel electrode 540, etc. The switching element Q and the pattern element 960 may have a structure shown in FIG. 5 or FIG. 6, although not limited thereto. The pixel electrode 540 may be connected to the switching element Q, in particular, a drain electrode of the switching element Q, and may include a transparent conductive material, for example, indium-tin oxide (ITO) or indium-zinc oxide (IZO). The pixel electrode 540 may be in a layer level higher than the switching element Q and the pattern element 960, although not limited thereto.

The upper display panel 600 may include a substrate 610 and a color filter 620, a black matrix 630, and a reference electrode 640 that are disposed on the substrate 610.

The color filter 620 may overlap the pixel electrode 540, may transmit light having a predetermined range of wavelength, and may include organic material. The black matrix 630 may include black organic material or metal to block visible light. The reference electrode 640 may overlap the pixel electrode 540 and may include a transparent conductive material, for example, ITO, IZO, etc.

The two electrodes, the pixel electrode 540 and the reference electrode 640, and the liquid crystal layer 700 disposed between the two electrodes 540 and 640 may form a part of the display unit DU shown in FIG. 2, and the color filter 620 may form another part of the display unit DU. The black matrix 630 may be arranged in peripheries of the display unit DU or of the pixel electrode 540.

At least one of the color filter 620 and the black matrix 630 may be disposed on the lower display panel 500.

The pattern element 960 (and the marker) may be in the same layer level as at least one of the signal lines. The pattern element 960 (and the marker) may be disposed in the display unit DU, for example, may overlap the pixel electrode 540. However, the pattern element 960 may be disposed outside the display unit DU.

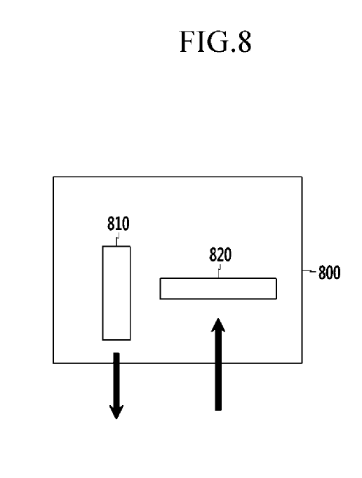

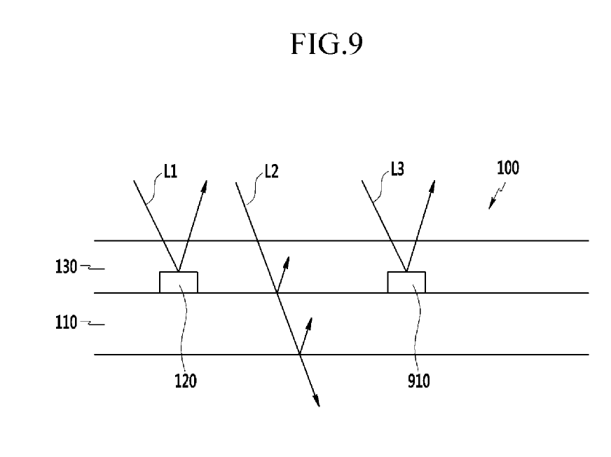

Hereinafter, operation of a display device for pattern recognition input according to an exemplary embodiment will be described in detail with reference to FIG. 8 and FIG. 9.

FIG. 8 is a schematic diagram of an electronic input pen, as a pointing device, that can be used for a display device for pattern recognition input according to an exemplary embodiment, and FIG. 9 is a schematic sectional view showing proceeding and reflecting paths of light incident from the pen on the display device shown in FIG. 3.

An electronic pen 800 including a light source 810 and a light sensor 820 as shown in FIG. 8 may be used as an input device for the display device for pattern recognition input shown in FIG. 1 to FIG. 7.

Referring to FIG. 9, a part of the light, for example, infrared light generated by the light source 810, may be reflected by the surfaces of the signal line 120, the pattern element 910, the substrate 110 or the insulating layer 130, and other part of the light may pass through the insulating layer 130 and the substrate 110 to ultimately be transmitted from the display device. In the exemplary liquid crystal display 400 shown in FIG. 7, there may be light reflections by the layers in the upper display panel 600, and in particular, the reflection by the color filter 620 may be predominant.

The light sensor 820 may detect the reflected light and determine the existence and the position of the pattern element 910. In detail, the light L1 and L3 reflected by the signal line 120 and the pattern element 910 may be stronger than the light L2 reflected by other elements of the display device. In other words, the reflectance of the signal line 120 and the pattern element 910 may be significantly higher than that of the other elements of the display device. Furthermore, to enhance the sensibility of detection of the reflected light, the pattern element 910 may be formed to have higher light reflectance than the signal line 120.

Therefore, by comparing the intensity of reflected lights, it may be determined that the signal line 120 or the pattern element 910 exists at a position where the intensity of the reflected light is high. Since the shape and the position of the signal line 120 is substantially the same but not different pixel by pixel, the position of the pattern element 910 may be easily found out.

Once the positions of the pattern elements 910 in the location indicator are found, a corresponding location of the pointing device on a screen may be determined by using a table, etc., stored therein.

Referring again to FIG. 7, in an alternative exemplary embodiment of the present invention, the pattern element 960 in the liquid crystal display 400 may be in the same layer level as the black matrix 630 including organic insulating material instead of as the electrodes or the signal lines. In such an exemplary embodiment, the black matrix 630 may be in the lower display panel 500 as described above, and then the pattern element 960 may be also in the lower display panel 500.

However, the difference between the reflectance of the black matrix 630 and the reflectance of other portions except for the signal lines, the electrodes, and the pattern element 960 may be smaller than the difference between the reflectance of the signal lines, the electrodes, or the pattern element 960 and the reflectance of the other portions, and thus the detection of the reflected light by pattern element 960 may be relatively difficult.

In addition, since organic insulating material has a lower process resolution than a metal, the area and the thickness of a pattern element including the organic insulating material may be greater than a pattern element including the metal, and thus the pattern element including the organic insulating material may decrease the luminance and the evenness of the display panel.

While this disclosure has been described in connection with what is presently considered to be practical exemplary embodiments, it is to be understood that the invention is not limited to the disclosed exemplary embodiments, but, on the contrary, is intended to cover various modifications and equivalent arrangements included within the spirit and scope of the appended claims.

What is claimed is:

1. A display device, comprising:
a substrate;
a plurality of signal lines disposed on the substrate;
at least one insulating layer disposed on the substrate; and
a plurality of location references disposed on the substrate and in the same layer level as at least one of the signal lines,
wherein arrangement of the plurality of location references varies depending on relative locations of the location references on a screen of the display device.

2. The display device of claim 1, wherein the plurality of location references are grouped into a plurality of location indicators, and the arrangement of the location references in one of the plurality of location indicators is different from the arrangement of the location references in the others of the plurality of location indicators.

3. The display device of claim 2, further comprising at least one marker disposed on the substrate and is in the same layer level as the location references.

4. The display device of claim 3, wherein the plurality of signal lines comprise:
a scanning line to transmit a scanning signal; and
a data line to transmit an image signal and having a layer level different from the scanning line,
wherein the location references are in the same layer level as one of the scanning line and the data line, and
the at least one insulating layer comprises a first insulating layer disposed between the scanning line and the data line.

5. The display device of claim 4, further comprising a switching element and a display unit,
wherein the switching element comprises:
a gate electrode connected to the scanning line and in the same layer level as the scanning line;
source and drain electrodes, either of which is connected to the data line and is in the same layer level as the data line; and
a semiconductor layer disposed apart from the gate electrode and connected to the source and drain electrodes.

6. The display device of claim 5, wherein the display unit comprises:
a pixel electrode connected to the switching element;
a reference electrode overlapping the pixel electrode;
a liquid crystal layer disposed between the pixel electrode and the reference electrode;
a color filter overlapping the pixel electrode; and
a black matrix disposed in a periphery of the pixel electrode,
wherein the location references are in a different layer level from the black matrix.

7. A display device, comprising:
a first substrate;
a gate electrode disposed on the first substrate;
a gate insulating layer disposed on the gate electrode;
a semiconductor layer disposed on the gate insulating layer;
source and drain electrodes disposed on the semiconductor layer;
a passivation layer disposed on the source and drain electrodes; and
a plurality of location references in the same layer level as the gate electrode or the source and drain electrodes,
wherein arrangement of the plurality of location references varies depending on relative locations of the location references on a screen of the display device.

8. The display device of claim 7, wherein the plurality of location references are grouped into a plurality of location indicators, and the arrangement of the location references in one of the plurality of location indicators is different from the arrangement of the location references in the others of the plurality of location indicators.

9. The display device of claim 8, further comprising at least one marker disposed on the substrate and in the same layer level as the location references.

10. The display device of claim 9, further comprising:
a scanning line connected to the gate electrode and in the same layer level as the gate electrode; and
a data line connected to the source electrode and in the same layer level as the source and drain electrodes.

11. The display device of claim 10, further comprising:
a pixel electrode connected to the drain electrode;
a second substrate facing the first substrate;
a reference electrode disposed on the second substrate; and
a liquid crystal layer disposed between the pixel electrode and the reference electrode.

12. The display device of claim 11, further comprising:
a color filter overlapping the pixel electrode; and
a black matrix disposed in a periphery of the pixel electrode and in a different layer level from the location references.

13. A display device, comprising:
a substrate;
a plurality of signal lines disposed on the substrate;
at least one insulating layer disposed on the substrate;
a plurality of pixels disposed on the substrate; and
a plurality of pattern elements disposed on the substrate in correspondence with some or all of the plurality of pixels,
wherein the plurality of pattern elements are grouped into a plurality of location indicators, each of the location indicators has distinct arrangement pattern from the other location indicators, and the plurality of pattern elements are in the same layer level as at least one of the signal lines.

14. The display device of claim 13, wherein the plurality of pattern elements overlap the respective plurality of pixels.

15. The display device of claim 13, wherein the plurality of pattern elements are outside the respective plurality of pixels.

16. The display device of claim 13, wherein the plurality of pattern elements are in the same layer level as the topmost signal line.
